(19) United States
(12) Patent Application Publication
(10) Pub. No.: US 2005/0262417 A1
(43) Pub. Date: Nov. 24, 2005

(54) Circuit and method for encoding data and data recorder

(76) Inventors: Miyuki Okamoto, Hashima-City (JP); Masato Fuma, Ichinomiya-City (JP); Shin'ichiro Tomisawa, Mizuho city (JP); Satoshi Noro, Anpachigun (JP); Hidemitsu Senoo, Higashi-osaka city (JP)

Correspondence Address: MCDERMOTT WILL & EMERY LLP, 600 13TH STREET, N.W., WASHINGTON, DC, 20005-3096, US

(21) Appl. No.: 11/133,459

(22) Filed: May 20, 2005

(30) Foreign Application Priority Data
May 21, 2004 (JP) 2004-152516 (P)

(51) Int. Cl. H03M 13/00

(52) U.S. Cl. 714/752

(57) ABSTRACT

To provide a data encoding circuit capable of securing real-timeness of a recording operation even in a memory of a low operation clock frequency by reducing the number of times of accessing the memory, and simultaneously reducing power consumption and memory costs. Prior to its writing in a memory (101), data from a host is processed by an EDC arithmetic operation circuit (110) and a scrambling arithmetic operation circuit (111), and written in the memory (101). Next, error correction encoding of a PO direction is executed at a PO arithmetic operation circuit (105), and an obtained PO code is added to corresponding data to be written in the memory (101). Subsequently, the data are read in a PI direction line by line from the memory (101) to a PI arithmetic operation circuit (112). A PI code is added to the data, and the data are sequentially output to a modulation circuit (200). Thus, it is possible to omit memory access when the data is written from the host in the memory, memory access when the data is read from the memory to the EDC arithmetic operation circuit, memory access when the data is read from the memory (101) to the modulation circuit (200), and memory access when the error correction code is written from the PI arithmetic operation circuit in the memory. As a result, it is possible to greatly reduce an operation clock frequency of the memory.

### BACKGROUND OF THE INVENTION

1. Field of the Invention

The present invention relates to a circuit and a method for encoding data, and a data recorder. In particular, the present invention is suitably used when error correction codes are added by product encoding of row (PI) and column (PO) directions.

2. Description of the Related Art

When data is recorded on a digital versatile disk (DVD), an error correction code is added for each ECC block. This error correction is carried out by using product codes. Error correction codes of row (PI) and column (PO) directions are added to data of one ECC block spread in the memory.

FIG. 4 shows a structure of an ECC block to which an error correction code is added. As shown in the drawing, one ECC block includes data of 208 rows and 181 columns. PO and PI codes are added in the 192nd to 208th rows and 172nd to 181st columns, respectively. Among those, the PI code is added to data of each row (data in sector), and the PO code is added to data of each column (data in sector). In other words, the PI code is calculated for the data of each row, and the PO code is calculated for each data of the column. The calculated PI and PO codes are added to their corresponding data to be stored in the memory.

The PO code corresponding to each column of a PI code area is stored in an overlapped portion of the PI and PO code areas. This is a case where processing of the PO direction is executed after processing of the PI direction. Conversely, however, even when the processing of the PI direction is executed after the processing of the PO direction, because of product code characteristics, the overlapped portion of the PI and PO code areas exhibits the same error correction operation.

FIG. 5 shows a configuration example (conventional example) of an error correction encoding circuit 100 which constitutes an ECC block by adding error correction codes to data. In the drawing, a memory 101 includes an SDRAM or the like. An EDC arithmetic operation unit 102 calculates and adds an error detection code to data. A scrambling arithmetic circuit 103 scrambles the data to which the error detection code has been added. A PI arithmetic operation circuit 104 calculates and adds an error correction code of a PI direction (row direction) to the scrambled data. A PO arithmetic operation circuit 105 calculates and adds an error correction code of a PO direction (column direction) to the scrambled data.

In the conventional error correction encoding circuit 100 shown in FIG. 5, first, after data of one ECC block is written from a host in the memory 101 (FIG. 6A), data of one sector is read by the EDC arithmetic operation circuit 102, a header containing a sector ID or the like is added, and then an error detection code (EDC) is added (FIG. 6B). Then, the data of one sector to which the error detection code has been added is scrambled by the scrambling arithmetic operation circuit 103 (FIG. 6C), and the scrambled data of one sector is subsequently written back in the memory 101.

Then, data are read line by line from the memory 101 to the PI arithmetic operation circuit 104, and a PI code is calculated for each line. The obtained PI code is added to its corresponding data to be written in the memory 101 (FIG. 6D). Then, when calculation and addition of PI codes are finished for all the lines, data are next read column by column, and a PO code is calculated for each PO code. The obtained PO code is added to its corresponding data to be written in the memory 101 (FIG. 6E). Accordingly, the ECC block shown in FIG. 4 is constituted in the memory 101.

Accordingly, after the ECC block has been constituted, data is read for each line, and output to a modulation circuit 200 (FIG. 6F). The modulation circuit 200 executes predetermined modulation to the input data to generate a recording signal. Such recording signals are sequentially recorded on a disk by an optical pickup 300.

Incidentally, in the error correction encoding circuit 100 shown in FIG. 5, when error correction encoding is carried out, access is frequently made from each circuit to the memory 101. In other words, when data of one ECC block is processed, the following process is carried out for the memory 101:
(1) data is written from the host (W);
(2) data is read by the EDC arithmetic operation circuit 102 (R);
(3) data is written by the scrambling arithmetic operation circuit 103 (W);
(4) data is read by the PI arithmetic operation circuit 104 (R);
(5) PI code is written by the PI arithmetic operation circuit 104 (W);
(6) data is read by the PO arithmetic operation circuit 105 (R);
(7) PO code is written by the PO arithmetic operation circuit 105 (W); and
(8) data is read to the modulation circuit 200 (R).

On the other hand, a relation with a DVD standard requires 11.08 Mbps as user data transfer rate during recording when data is recorded at a speed multiplied by 1. This is expressed to be 0.6925 Mword/S by a word (16 bits) unit.

In the error correction encoding circuit 100 shown in FIG. 5, assuming that access to the memory 101 is processed by 16 bits, the number of times of accessing the memory 101 shown in the process (1) to (8) is multiplied by the user data transfer rate 0.6925 Mword/S expressed by the word to obtain a frequency of an operation clock necessary for the memory access. Here, if the number of accessing times of (5) is about 0.2 since the access of (5) is for writing the PI code, and the number of accessing times of (7) is about 0.3 since the access of (7) is for writing the PO code, a clock frequency CL₁ necessary for operating the memory 101 is obtained by the following equation.
CL₁=6.5×0.6925=4.5 MHz (1)

This clock frequency is in the case of recording at a speed multiplied by 1. When the speed is multiplied by 16, a clock frequency CL₁₆ is represented by the following equation.
CL₁₆=4.5×16=72 MHz (2)
Further, when an overhead of memory access is estimated to be about 1.3 to 1.5, a clock frequency is represented by the following equation.
CL₁₆=94 to 108 MHz (3)

In reality, memory access in addition to the process (1) to (8) is required. Accordingly, an operation clock of the memory must be much higher.

However, the memory of such a high clock frequency is expensive. Thus, a cost problem occurs when the memory is mounted on a DVD recorder or the like. Additionally, the high operation clock frequency of the memory brings about a problem with an increase in power consumption of the memory. On the other hand, if the operation clock frequency of the memory is reduced, encoding is not finished in time, causing a fear of losing real-timeness of the recording operation.

JP-2001-298371 A describes a technology of reducing the number of times of accessing a memory by simultaneously performing PI and PO arithmetic operations.

### SUMMARY OF THE INVENTION

The present invention has been made to solve the problems, and an object of the present invention is to secure real-timeness of a recording operation even with a memory of a low operation clock frequency by reducing the number of times of accessing the memory, and to simultaneously allow reduction in power consumption and in memory costs.

According to a first aspect of the present invention, there is provided a data encoding circuit, including: an EDC arithmetic operation unit for adding an error detection code to data; a scrambling arithmetic operation unit for scrambling the data to which the error detection code has been added by the EDC arithmetic operation unit; a PI arithmetic operation unit for adding an error correction code of a PI direction to the data scrambled by the scrambling arithmetic operation unit; a PO arithmetic operation unit for adding an error correction code of a PO direction to the data scrambled by the scrambling arithmetic operation unit; and a memory for writing/reading data in accordance with an operation clock, in which data from a host is input to the EDC arithmetic operation unit and the scrambling arithmetic operation unit to be processed before writing of the data in the memory, the processed data is written in the memory, one of the PI arithmetic operation unit and the PO arithmetic operation unit executes processing first on the data in a direction different from a data reading direction for outputting data from the memory to a processing circuit of a subsequent stage to write in the memory the error correction code, and the other one of the PI arithmetic operation unit and the PO arithmetic operation unit executes processing next on the data while reading the data from the memory in the data reading direction to add the error correction code thereto and sequentially output the data to the processing circuit of the subsequent stage.

According to a second aspect of the present invention, there is provided a method of encoding data, including: an EDC arithmetic operation step of adding an error detection code to data; a scrambling arithmetic operation step of scrambling the data to which the error detection code has been added in the EDC arithmetic operation step; a PI arithmetic operation step of adding an error correction code of a PI direction to the data scrambled in the scrambling arithmetic operation step; and a PO arithmetic operation step of adding an error correction code of a PO direction to the data scrambled in the scrambling arithmetic operation step, in which data from a host is processed in the EDC arithmetic operation step and the scrambling arithmetic operation step to be written in a memory, one of the PI arithmetic operation step and the PO arithmetic operation step includes executing processing first on the data in a direction different from a data reading direction for outputting data from the memory to a processing circuit of a subsequent stage to write in the memory the error correction code, and the other one of the PI arithmetic operation step and the PO arithmetic operation step includes executing processing next on the data while reading the data from the memory in the data reading direction to add the error correction code thereto and sequentially output the data to the processing circuit of the subsequent stage.

According to a third aspect of the present invention, there is provided a data recorder equipped with a data encoding circuit for adding an error correction code to recorded data, the data encoding circuit including: an EDC arithmetic operation unit for adding an error detection code to data; a scrambling arithmetic operation unit for scrambling the data to which the error detection code has been added by the EDC arithmetic operation unit; a PI arithmetic operation unit for adding an error correction code of a PI direction to the data scrambled by the scrambling arithmetic operation unit; a PO arithmetic operation unit for adding an error correction code of a PO direction to the data scrambled by the scrambling arithmetic operation unit; and a memory for writing/reading data in accordance with an operation clock, in which data from a host is input to the EDC arithmetic operation unit and the scrambling arithmetic operation unit to be processed before writing of the data in the memory, the processed data is written in the memory, one of the PI arithmetic operation unit and the PO arithmetic operation unit executes processing first on the data in a direction different from a data reading direction for outputting data from the memory to a processing circuit of a subsequent stage to write in the memory the error correction code, and the other one of the PI arithmetic operation unit and the PO arithmetic operation unit executes processing next on the data while reading the data from the memory in the data reading direction to add the error correction code thereto and sequentially output the data to the processing circuit of the subsequent stage.

According to each aspect of this invention, the data from the host is input to the EDC arithmetic operation unit and the scrambling unit to be processed prior to its writing in the memory, and then the data is written from the scrambling unit in the memory. Thus, it is possible to omit memory access when the data is written from the host in the memory and memory access when the data is read from the memory to the EDC arithmetic operation unit. Moreover, the error correction codes of a PI or PO direction are added while the data is read in the PI or PO direction from the memory, and these codes are sequentially output to the processing unit or the like of the subsequent stage. Thus, it is possible to omit memory access when the data is read from the memory to the processing unit or the like of the subsequent stage and memory access when the error correction code is added from the PI arithmetic operation unit or the PO arithmetic operation unit and written in the memory.

Thus, according to this invention, as compared with the conventional technology, the number of times of accessing the memory can be considerably reduced, making it possible to conspicuously reduce the operation clock frequency of the memory.

For example, when this invention is applied to a DVD recorder, the number of times of accessing a memory can be reduced from 6.5 (conventional technology) to 3.3 (this invention). Thus, in accordance with the equations (1) to (3), the operation clock frequency of the memory is represented as follows in the case of a speed multiplied by 1.
CL₁=3.3×0.6925=2.29 MHz
In the case of a speed multiplied by 16, the operation clock frequency is represented as follows.
CL₁₆=2.29×16=36.6 MHz
Further, when a memory access overhead of 1.3 to 1.5 is expected, the operation clock frequency is represented as follows.
CL₁₆=48 to 55 MHz

In addition, according to this invention, error correction codes of the PI or PO direction are not written in the memory. Thus, the memory capacity that would be required for the error correction codes can be saved. Alternatively, a free memory area created due to the fact that PI codes or PO codes are not written in the memory can be used as a work area for another process.

### BRIEF DESCRIPTION OF THE DRAWINGS

The above, other objects and novel features of the present invention will become more completely apparent upon reading the following embodiments in conjunction with the accompanying drawings, wherein:

FIG. 1 shows a configuration of a disk recorder according to Embodiment 1 of the present invention;

FIG. 2 is a flowchart of an error correction encoding process according to the Embodiment 1;

FIG. 3A is a conceptual diagram of the error correction encoding process of the Embodiment 2;

FIG. 3B is a conceptual diagram of the error correction encoding process of the Embodiment 2;

FIG. 4 is a diagram showing a structure of an ECC block;

FIG. 5 shows a configuration of a disk recorder of a conventional example;

FIG. 6A is a conceptual diagram of an error correction encoding process of the conventional example;

FIG. 6B is a conceptual diagram of the error correction encoding process of the conventional example;

FIG. 6C is a conceptual diagram of the error correction encoding process of the conventional example;

FIG. 6D is a conceptual diagram of the error correction encoding process of the conventional example;

FIG. 6E is a conceptual diagram of the error correction encoding process of the conventional example; and

FIG. 6F is a conceptual diagram of the error correction encoding process of the conventional example.

### DETAILED DESCRIPTION OF THE PREFERRED EMBODIMENT

The embodiment of the present invention will be described with reference to the accompanying drawings. This embodiment shows a configuration example when the present invention is applied to a DVD recorder.

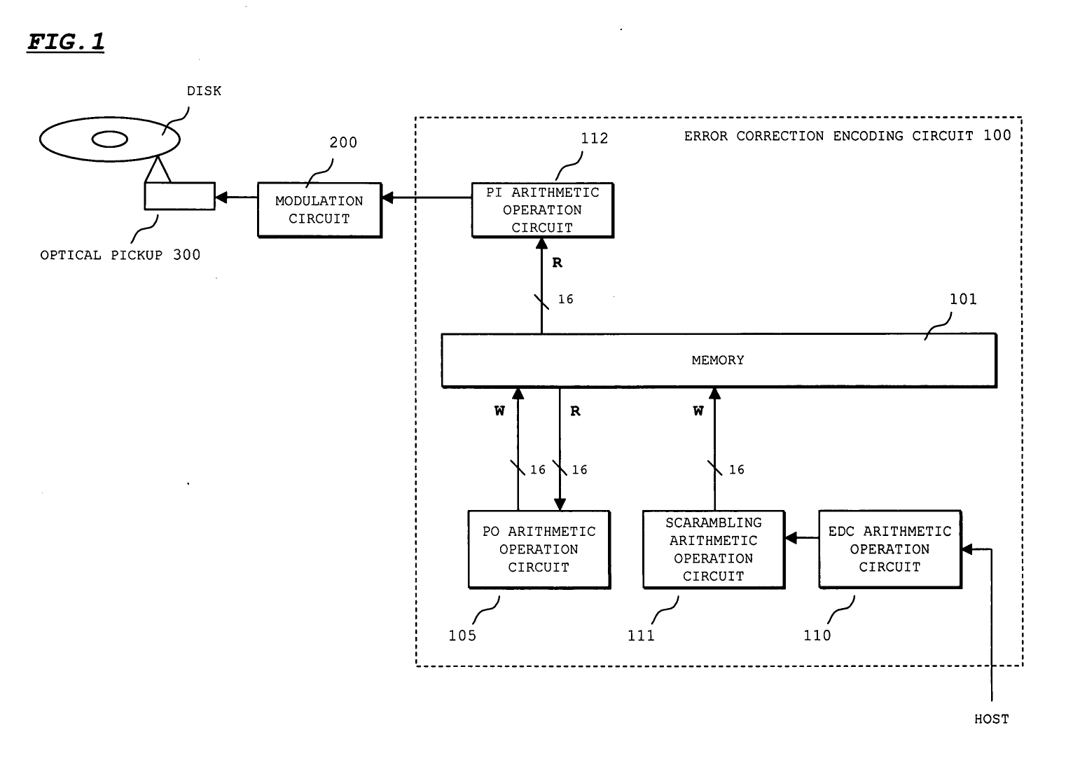

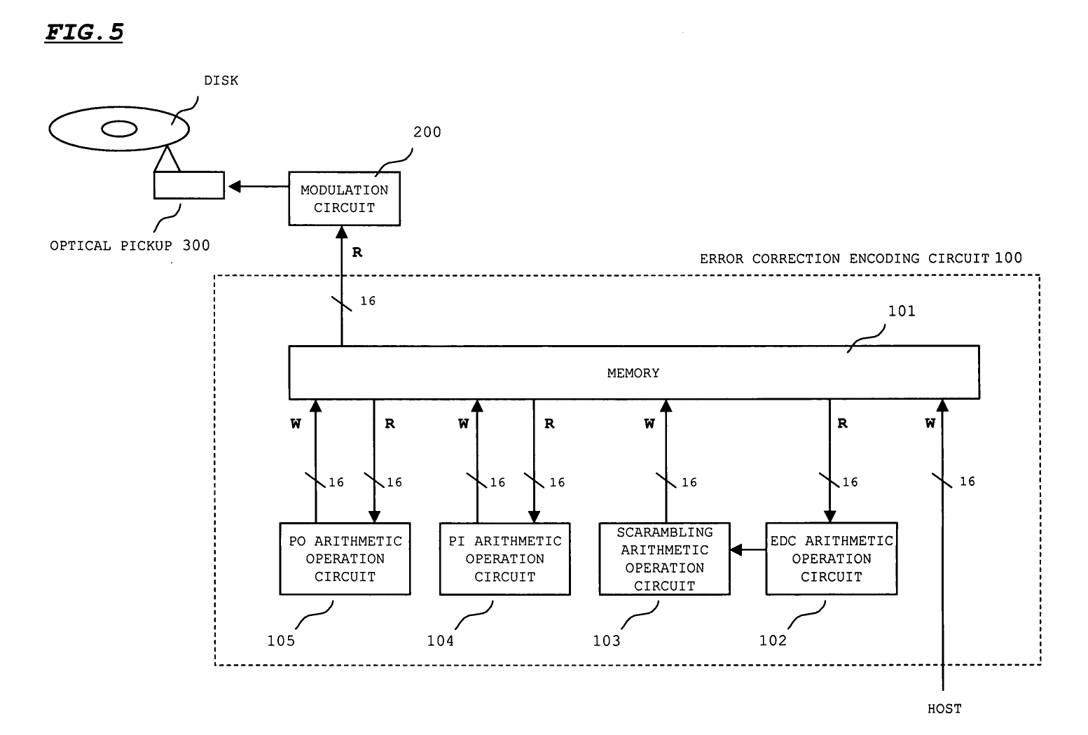

FIG. 1 shows a configuration of a disk recorder according to this embodiment. Portions similar to those of FIG. 5 are denoted by similar reference numerals.

A memory 101 includes an SDRAM or the like. A PO arithmetic operation circuit 105 calculates and adds an error correction code of a PO direction (column direction) to scrambled data. An EDC arithmetic operation circuit 110 calculates and adds an error detection code to data input from a host. A scrambling arithmetic operation circuit 111 scrambles the data to which the error correction code has been added. API arithmetic operation circuit 112 adds a PI code to the data input from the memory 101, and then outputs the data to a modulation circuit 200. The modulation circuit 200 executes predetermined modulation on the input data to generate a recording signal. An optical pickup 300 emits a laser beam in accordance with the recording signal input from the modulation circuit 200 to write data in an optical disk.

According to this embodiment, recorded data is input from a host to the EDC arithmetic operation circuit 110. Each time data of one ECC block is input, the EDC arithmetic operation circuit 110 calculates and adds an error detection code to the data and outputs this data to the scrambling arithmetic operation circuit 111. The scrambling arithmetic operation circuit 111 executes scrambling on the data of one ECC block input from the EDC arithmetic operation circuit 110, and sequentially writes the data in the memory 101.

Furthermore, according to this embodiment, prior to error correction encoding of a PI direction, error correction encoding of a PO direction is executed at the PO arithmetic operation circuit 105, and an obtained PO code is added to corresponding data to be written in the memory 101. Subsequently, the data are read in the PI direction line by line from the memory 101 to the PI arithmetic operation circuit 112. A PI code is added to the data, and the data is output directly to the modulation circuit 200.

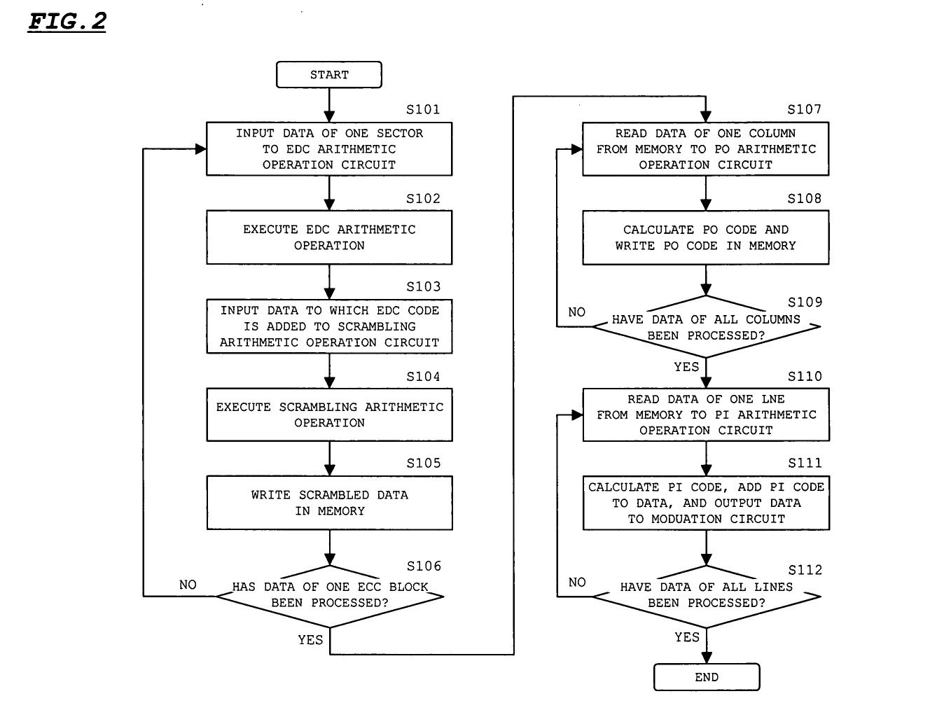

FIG. 2 is a flowchart showing an error correction encoding process for data of one ECC block.

When data of one sector (sector data) is input from the host to the EDC arithmetic operation circuit 110 (S101), a header containing a sector ID or the like is added to the sector data, followed by error detection code calculation (S102). The EDC code calculated here is added to the sector data and input to the scrambling arithmetic operation circuit 111 (S103). The scrambling arithmetic operation circuit 111 executes scrambling on the input sector data (S104). Then, the scrambled sector data is written in the memory 101 (S105). The process of steps S101 to S105 is repeated until the data of one ECC block has been written in the memory 101 (S106).

Thus, after the data of one ECC block has been written in the memory 101, then data of one column is read from the memory 101 to the PO arithmetic operation circuit 105 (S107), and then at the PO arithmetic operation circuit 105, error correction code calculation (PO code calculation) on the data is executed. An obtained PO code is added to the data and written in the memory 101 (S108). This process is repeated until completion for data of all the columns (S109).

Then, data of one line is read from the memory 101 to the PI arithmetic operation circuit 112 (S110), and the PI arithmetic operation circuit 112 executes error correction code calculation (PI code calculation) on the data. An obtained PI code is added to the data and output to the modulation circuit 200 (S111). This process is repeated until completion for data of all the lines (S112).

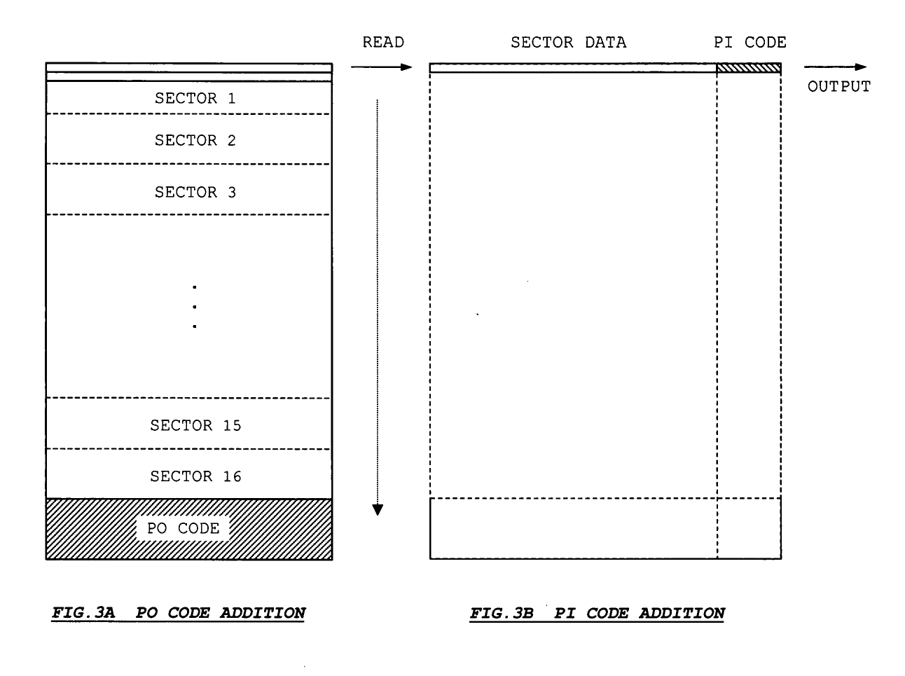

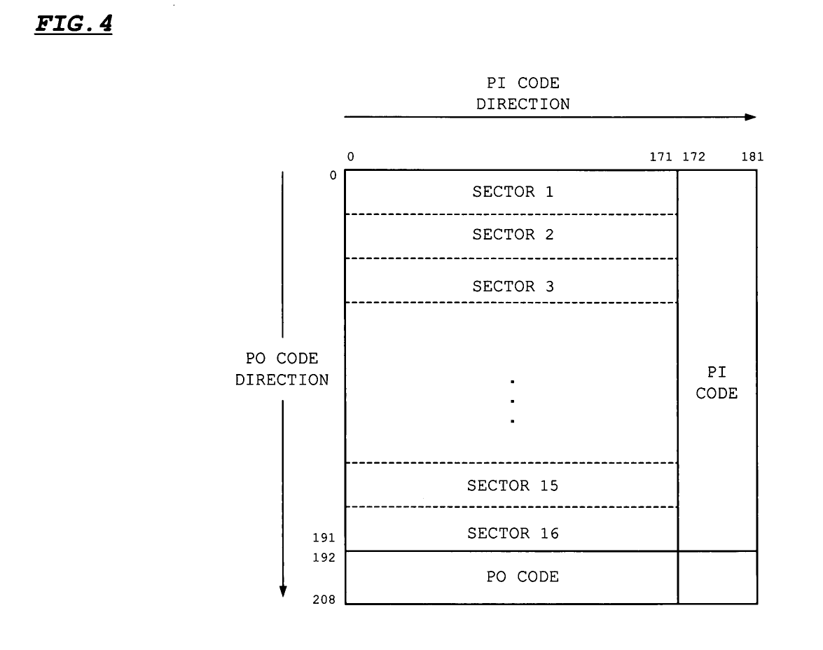

FIGS. 3A and 3B conceptually show the process of steps S110 to S112. The data constituted in the memory 101 in steps S101 to S109 (see FIG. 3A) are read sequentially from a head line, while PI codes are added to the data (see FIG. 3B). Then, the data are sequentially output to the modulation circuit 200 provided in the following stage, and recorded on the disk.

According to this embodiment, prior to writing of the data from the host in the memory 101, the data is input to the EDC arithmetic operation circuit 110 and the scrambling arithmetic operation circuit 111 and processed, and the processed data is written in the memory 101. Thus, it is possible to omit memory access when the data is written from the host in the memory and memory access when the data is read from the memory to the EDC arithmetic operation circuit.

The PI arithmetic operation is carried out while the data is read in the PI direction from the memory 101. Thus, it is possible to omit memory access when the data is read from the memory 101 to the modulation circuit 200 and memory access when the error correction code of the PI direction is added from the PI arithmetic operation circuit to be written in the memory.

Thus, according to this embodiment, the number of times of accessing the memory can be considerably reduced, making it possible to conspicuously reduce the operation clock frequency of the memory. As a result, it is possible to greatly reduce costs of the memory 101, realizing low costs of the data recorder.

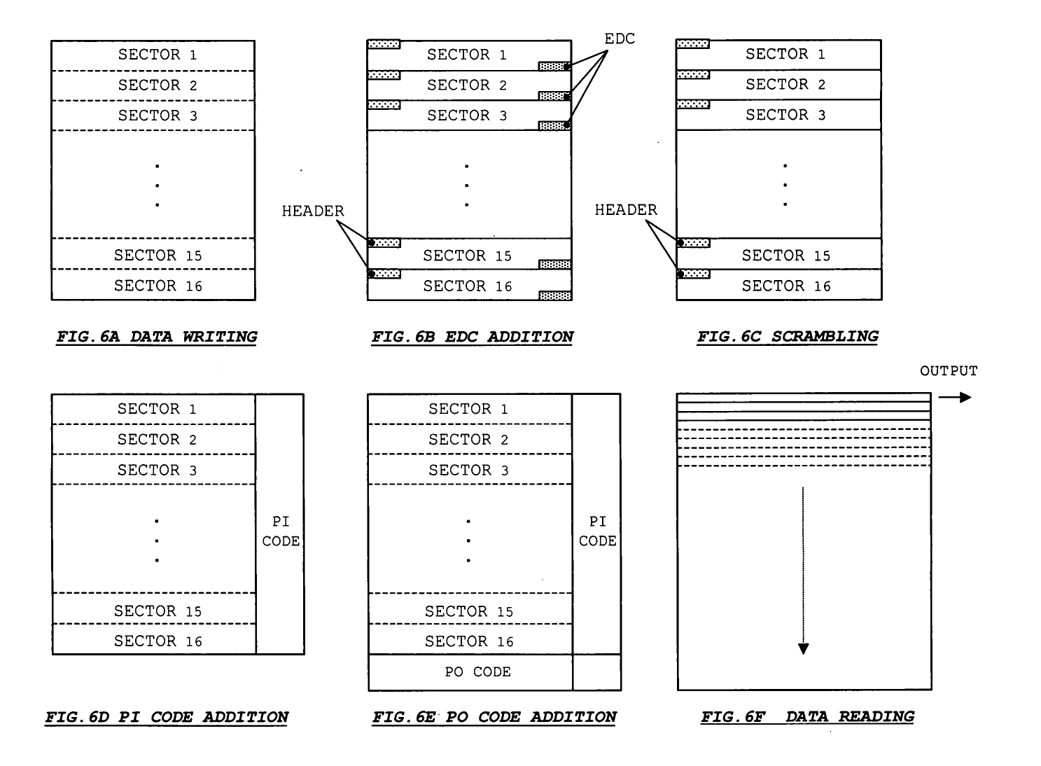

In addition, since PI codes are not written in the memory, the memory capacity that would be required for the PI codes can be saved. Alternatively, a free memory area created due to the fact that the PI codes are not written in the memory can be used as a work area for another process. In an ECC block including data of the rows and columns whose numbers are shown in FIG. 6, the PI code area has a data amount approximately corresponding to that of one sector, by which the memory capacity can be saved.

Hereinabove, description has been made of the present invention with reference to the embodiments. However, the present invention is not limited to the above-mentioned embodiments.

It should be noted that in the above-mentioned embodiments, since the PI direction is set as the direction for reading data from the memory when outputting data from the memory to the modulation circuit, the processing in the PO direction is executed first, and the PI encoding and output of the data to the modulation circuit 200 are executed next while the data are read in the PI direction. However, if the PO direction is set as the direction for reading data from the memory when outputting data from the memory to the modulation circuit, the processing in the PI direction is executed first, and the PO encoding and output of the data to the modulation circuit 200 are executed next while the data are read in the PO direction.

The present invention can be modified variously as appropriate within the technical thoughts described in the scope of the claims appended hereto.

1. A data encoding circuit, comprising:
an EDC arithmetic operation unit for adding an error detection code to data;
a scrambling arithmetic operation unit for scrambling the data to which the error detection code has been added by the EDC arithmetic operation unit;
a PI arithmetic operation unit for adding an error correction code of a PI direction to the data scrambled by the scrambling arithmetic operation unit;
a PO arithmetic operation unit for adding an error correction code of a PO direction to the data scrambled by the scrambling arithmetic operation unit; and
a memory for writing/reading data in accordance with an operation clock,
wherein data from a host is input to the EDC arithmetic operation unit and the scrambling arithmetic operation unit to be processed before writing of the data in the memory, the processed data is written in the memory, one of the PI arithmetic operation unit and the PO arithmetic operation unit executes processing first on the data in a direction different from a data reading direction for outputting data from the memory to a processing circuit of a subsequent stage to write in the memory the error correction code, and the other one of the PI arithmetic operation unit and the PO arithmetic operation unit executes processing next on the data while reading the data from the memory in the data reading direction to add the error correction code thereto and sequentially output the data to the processing circuit of the subsequent stage.

2. A method of encoding data, comprising:
an EDC arithmetic operation step of adding an error detection code to data;
a scrambling arithmetic operation step of scrambling the data to which the error detection code has been added in the EDC arithmetic operation step;
a PI arithmetic operation step of adding an error correction code of a PI direction to the data scrambled in the scrambling arithmetic operation step; and
a PO arithmetic operation step of adding an error correction code of a PO direction to the data scrambled in the scrambling arithmetic operation step,
wherein data from a host is processed in the EDC arithmetic operation step and the scrambling arithmetic operation step to be written in a memory, one of the PI arithmetic operation step and the PO arithmetic operation step includes executing processing first on the data in a direction different from a data reading direction for outputting data from the memory to a processing circuit of a subsequent stage to write in the memory the error correction code, and the other one of the PI arithmetic operation step and the PO arithmetic operation step includes executing processing next on the data while reading the data from the memory in the data reading direction to add the error correction code thereto and sequentially output the data to the processing step of the subsequent stage.

3. A data recorder equipped with a data encoding circuit for adding an error correction code to recorded data, the data encoding circuit comprising:
an EDC arithmetic operation unit for adding an error detection code to data;
a scrambling arithmetic operation unit for scrambling the data to which the error detection code has been added by the EDC arithmetic operation unit;
a PI arithmetic operation unit for adding an error correction code of a PI direction to the data scrambled by the scrambling arithmetic operation unit;
a PO arithmetic operation unit for adding an error correction code of a PO direction to the data scrambled by the scrambling arithmetic operation unit; and
a memory for writing/reading data in accordance with an operation clock,
wherein data from a host is input to the EDC arithmetic operation unit and the scrambling arithmetic operation unit to be processed before writing of the data in the memory, the processed data is written in the memory, one of the PI arithmetic operation unit and the PO arithmetic operation unit executes processing first on the data in a direction different from a data reading direction for outputting data from the memory to a processing circuit of a subsequent stage to write in the memory the error correction code, and the other one of the PI arithmetic operation unit and the PO arithmetic operation unit executes processing next on the data while reading the data from the memory in the data reading direction to add the error correction code thereto and sequentially output the data to the processing circuit of the subsequent stage.
